(19) United States
(12) Patent Application Publication
(10) Pub. No.: US 2016/0379848 A1
(43) Pub. Date: Dec. 29, 2016

(54) Substrate Processing Apparatus

(71) Applicant: Hitachi Kokusai Electric Inc., Tokyo (JP)

(72) Inventors: Yoshihiko YANAGISAWA, Toyama (JP); Hidehiro YANAI, Toyama (JP)

(21) Appl. No.: 15/260,028

(22) Filed: Sep. 8, 2016

Related U.S. Application Data
(63) Continuation of application No. PCT/JP2015/059086, filed on Mar. 25, 2015.

(30) Foreign Application Priority Data
Mar. 26, 2014 (JP) 2014-064069

(51) Int. Cl. H01L 21/67; H01L 21/687

(52) U.S. Cl. CPC H01L 21/67069; H01L 21/68742; H01L 21/67109

(57) ABSTRACT

A substrate processing apparatus includes: a processing chamber for processing a substrate; a substrate holding part whereon the substrate is placed; an elevating mechanism to move the substrate holding part vertically; a first gas supply system to supply a halogen-containing process gas to the substrate; a second gas supply system to supply an inert gas to the substrate; an exhaust unit to exhaust the process and inert gases; and a controller to control the elevating mechanism and the gas supply systems to: supply the process gas with a state where heights of the substrate holding part and exhaust unit are adjusted; and supply the inert gas to a center portion of the substrate from thereabove such that the inert gas flows radially from the center portion to a circumference of the substrate along a surface of the substrate and is exhausted out of the processing chamber through the exhaust unit.

### CROSS REFERENCE TO RELATED APPLICATIONS

This application is a continuation of International Application No. PCT/JP2015/059086, filed on Mar. 25, 2015, which claims priority under 35 U.S.C. §119 to Japanese Patent Application No. 2014-064069 filed on Mar. 26, 2014, the entire contents of which are hereby incorporated by reference.

### FIELD OF THE INVENTION

The present disclosure relates to a substrate processing apparatus for processing a substrate.

### BACKGROUND

As large-scale integrated circuits (hereinafter referred to as LSIs') become finer, patterning technology has been more finely developed. Examples of patterning technology are disclosed in Japanese Unexamined Patent Application Publication No. 2010-212371 and Japanese Unexamined Patent Application Publication No. 2012-94652.

An etching process which is one of processes of manufacturing a semiconductor device has the following problem. For example, when a substrate including a silicon (Si)-containing film is etched, a residue such as a very small amount of a silicon film remains on the substrate or a by-product which is a compound of a gas used to etch the substrate and silicon is generated. In the related art, in order to solve this problem, an etched substrate is heated in an annealing chamber to a temperature at which a residue or a by-product remaining on the substrate sublimates.

### SUMMARY

Described herein is a technique to solve a degradation of film uniformity and selectivity on a substrate caused by a residue or a by-product remaining on the substrate when the substrate is etched.

According to one embodiment described herein, a substrate processing apparatus includes: a processing chamber where a substrate including a silicon film on a portion of surface thereof is processed; a substrate holding part whereon the substrate is placed; an elevating mechanism configured to move the substrate holding part up and down; a first gas supply system configured to supply a process gas containing a halogen element to the substrate; a second gas supply system configured to supply an inert gas for exhausting the process gas out of the processing chamber to the substrate; an exhaust unit disposed about a sidewall of the processing chamber and configured to exhaust the process gas and the inert gas; and a controller configured to control the elevating mechanism, the first gas supply system and the second gas supply system to: supply the process gas with a state where a height of the substrate holding part and a height of the exhaust unit are adjusted; and supply the inert gas to a center portion of the substrate from thereabove such that the inert gas flows radially from the center portion to a circumferential portion of the substrate along a surface of the substrate and is exhausted out of the processing chamber through the exhaust unit.

### BRIEF DESCRIPTION OF THE DRAWINGS

FIG. 1 is a diagram illustrating a structure of a substrate processing apparatus showing a state in a substrate processing suitably used in the embodiment described herein.

FIG. 2 is a diagram illustrating a structure of a substrate processing apparatus showing a state before the substrate processing suitably used in the embodiment described herein.

FIG. 3 is a diagram illustrating an example of another structure of a substrate processing apparatus showing a state in a substrate processing suitably used in the embodiment described herein.

FIG. 4 is a top view of a transfer system employed in a substrate processing apparatus according to an exemplary embodiment described herein.

FIG. 5 is a diagram illustrating a structure of a controller of a substrate processing apparatus suitably used in the embodiment described herein.

FIG. 6 is a flowchart illustrating substrate processing performed by a substrate processing apparatus suitably used in the embodiment described herein.

Next, exemplary embodiments will be described.

### DETAILED DESCRIPTION

### Exemplary Embodiments

Hereinafter, exemplary embodiments will be described in more detail with reference to the accompanying drawings.

### (1) Structure of Substrate Processing Apparatus

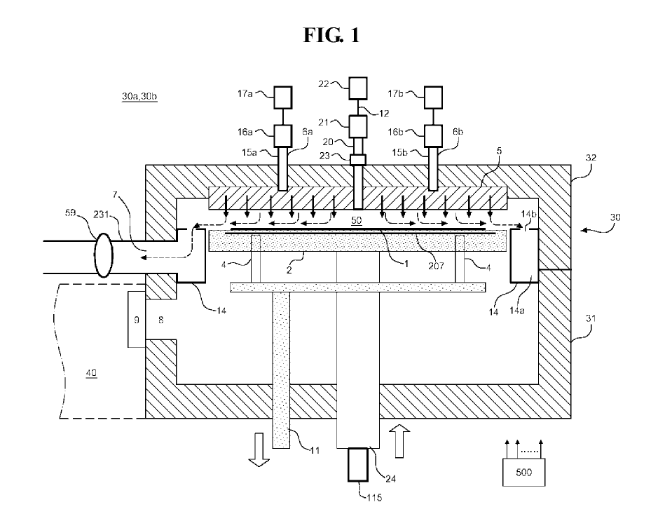

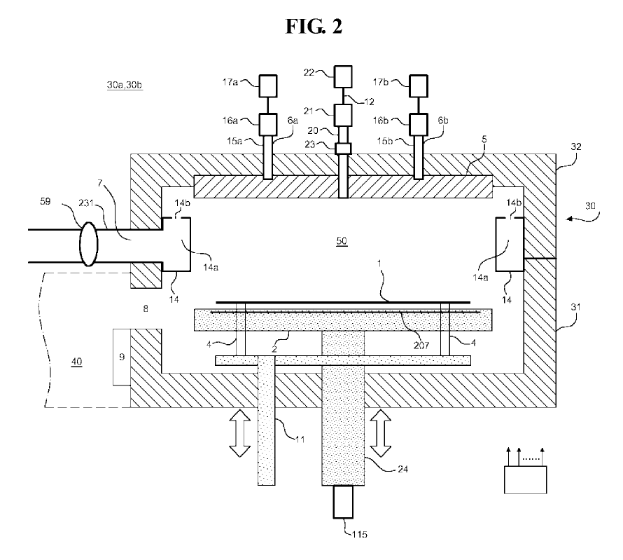

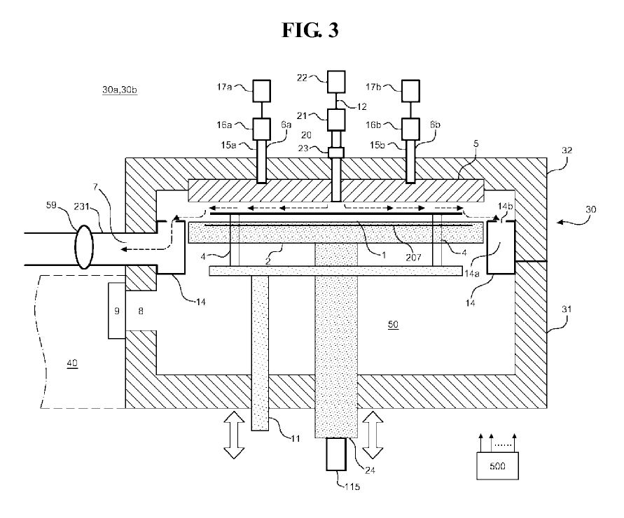

FIG. 1 is a cross-sectional view of main elements of a single-wafer substrate processing apparatus (hereinafter referred to as a “substrate processing apparatus”) configured to perform a semiconductor device manufacturing process. FIG. 1 illustrates a state in which a substrate is processed, i.e., a state in which a susceptor therein which is a substrate holding part is moved up to a first processing position to process the substrate. FIG. 2 is also a cross-sectional view of the main elements of the substrate processing apparatus. FIG. 2 illustrates a state in which the susceptor is moved down to a transfer position to transfer the substrate. FIG. 3 illustrates a state in which a substrate support pin elevating mechanism is moved up to a second processing position to process a substrate in the state illustrated in FIG. 1.

Referring to FIGS. 1 through 3, the substrate processing apparatus includes a processing container 30 including a substrate processing chamber 50 configured to process a substrate 1 therein, and a substrate transfer chamber 40 which is disposed adjacent to the processing container 30 and to which the substrate 1 is transferred.

The processing container 30 includes a container body 31 having an open upper end and a lid 32 configured to block the opening in the upper end of the container body 31. The substrate processing chamber 50 having a closed structure is included in the processing container 30. The substrate processing chamber 50 may be provided in a space surrounded by the lid 32 and a susceptor 2.

A shower head 5 as a gas supply unit, gas supply lines 6a and 6b, which is a gas supply system, connected to the shower head 5, and an inert gas supply line 12 installed separately from the gas supply lines 6a and 6b and connected to the shower head 5 in order to supply an inert gas into the substrate processing chamber 50 apart from the gas supply lines 6a and 6b are installed in the lid 32. The shower head 5 may be installed to face the substrate 1 within the substrate processing chamber 50 and may supply a process gas to an entire surface of a substrate into the substrate processing chamber 50. The shower head 5 is installed in an upper portion of the inside of the lid 32, and includes a gas dispersing plate (not shown) with a plurality of gas supply holes via which a gas is showered and a mixing chamber (not shown) for mixing a plurality of gases.

The gas supply lines 6a and 6b are configured to supply a process gas into the substrate processing chamber 50 via the shower head 5. In detail, the gas supply lines 6a and 6b include gas supply pipes 15a and 15b connected to the shower head 5 and communicating with the mixing chamber, and flow rate controllers (mass flow controllers, MFCs) 16a and 16b installed at the gas supply pipes 15a and 15b. The gas supply lines 6a and 6b are configured to supply a desired gas into the substrate processing chamber 50 at a desired flow rate and in a desired ratio. The gas supply lines 6a and 6b may further include gas supply sources 17a and 17b.

A gas exhaust system includes an exhaust pipe 231 that constitutes an exhaust port 7 installed above the substrate processing chamber 50 (the lid 32), an annular member 14 which is a buffer exhaust pipe including an adjusting unit 14b configured to adjust a flow rate of an exhaust gas exhausted from the substrate processing chamber 50 and an annular exhaust channel 14a for inducing an exhaust gas introduced via the adjusting unit 14b to flow into the exhaust port 7, and a valve 59 configured to control an internal pressure of the substrate processing chamber 50. The gas exhaust system may further include a vacuum pump (not shown) configured to exhaust an exhaust gas from the substrate processing chamber 50. The annular member 14 has a ring shape or a donut shape. A cross-section of the annular exhaust channel 14a is not limited to a tetragonal shape illustrated in FIGS. 1 through 3, and may have, for example, a triangular shape. A rate of exhausting the exhaust gas via the exhaust port 7 may be adjusted by setting a cross-sectional area of the annular exhaust channel 14a to be greater than that of the exhaust port 7. For example, the rate of exhausting the exhaust gas via the exhaust port 7 may be adjusted to be low. The exhaust gas is a gas exhausted from the substrate processing chamber 50. The exhaust gas includes, for example, a non-reactive process gas and a non-reactive inert gas. An inert gas introduced into the substrate processing chamber 50 via a central portion of the shower head 5 flows uniformly and radially from a central portion of the substrate 1 to a circumferential portion thereof. A process gas may be efficiently discharged (purged) by the inert gas. The annular member (the buffer exhaust pipe) 14 installed near the circumferential portion of the substrate 1 is controlled to efficiently discharge (purge) a process gas, as well as the automatic pressure control (APC) valve 59 or the vacuum pump.

The susceptor 2 including a heater 207 therein which is a heating unit and a transfer port 8 are installed in the container body 31. The transfer port 8 is installed at the same sidewall of the container body 31 below the exhaust port 7. The unprocessed substrate 1, such as a silicon wafer, is loaded from the substrate transfer chamber 40 into the substrate processing chamber 50 within the processing container 30 via the transfer port 8. The processed substrate 1 is unloaded from substrate processing chamber 50 to the substrate transfer chamber 40 via the transfer port 8. An opening/closing valve 9 for isolating atmospheres of the substrate transfer chamber 40 and the substrate processing chamber 50 is installed to be opened or closed with respect to the transfer port 8 of the container body 31.

The susceptor 2 is installed to be moved up and down within the substrate processing chamber 50 of the processing container 30. The substrate 1 is placed on a surface of the susceptor 2. The substrate 1 is heated by the heater 207 of the susceptor 2.

A plurality of support pins 4 are installed to be perpendicular to a substrate support pin elevating mechanism 11. The support pins 4 may pass through the heater 207 and the susceptor 2, and may protrude from a surface of the susceptor 2 according to the ascent and descent movement of the susceptor 2 and the substrate support pin elevating mechanism 11.

When the susceptor 2 is moved down so that the substrate processing apparatus may transfer the substrate 1 [see FIG. 2, a position of the susceptor 2 in this case will be hereinafter referred to as a transfer position A], the support pins 4 protrude from the susceptor 2 and support the substrate 1 from below the substrate 1. The substrate 1 may be transferred between the substrate processing chamber 50 and the substrate transfer chamber 40 via the transfer port 8. That is, the substrate 1 may be loaded into or unloaded from the substrate processing chamber 50. When the susceptor 2 is moved up to the first processing position higher than the transfer position A [see FIG. 1, the first processing position will be hereinafter referred to as a substrate processing position B] so as to process the substrate 1, the substrate 1 is transferred from the support pins 4 to the susceptor 2.

The susceptor 2 may be moved up and down within the substrate processing chamber 50 by an elevating mechanism being connected to a support shaft 24 of the susceptor 2. A bellows (not shown) accommodating the support shaft 24 is installed to surround the support shaft 24. An elevating mechanism 115 is configured to adjust a position of the susceptor 2 within the substrate processing chamber 50 to multiple levels, such as the transfer position A and the substrate processing position B, in a substrate loading step, a substrate processing step and a substrate unloading step.

The susceptor 2 is configured to be rotatable. That is, the support shaft 24 having a cylindrical shape described above may be rotated by a rotating mechanism (not shown). The susceptor 2 including a heater therein is installed to be rotatable about the support shaft 24. The susceptor 2 may be rotated at an arbitrary speed while the substrate 1 is retained thereon. A resistive heater is installed to be fixed in the susceptor 2 and is supported by a fixing unit (not shown) inserted into the support shaft 24 having the cylindrical shape to pass through the support shaft 24. As described above, since the susceptor 2 is rotatable and the resistive heater is fixed therein, the susceptor 2 may be rotated relative to the resistive heater.

As illustrated in FIG. 1, in the present embodiment, the gas supply lines 6a and 6b installed in the upper portion of the lid 32 of the processing container 30 include the process gas supply line 6a, which is a first gas supply system configured to introduce a process gas, and the non-reactive gas supply line 6b, which is a third gas supply system configured to introduce a non-reactive gas for controlling the process gas. The inert gas supply line 12, which is a second gas supply system, is installed in a roughly central portion of the shower head 5 facing the central portion of the substrate 1. The process gas supply line 6a and the non-reactive gas supply line 6b are connected to a portion of the shower head 5 facing the central portion of the substrate 1 other than the roughly central portion of the shower head 5. In the following description, the term “non-reactive gas” may be used interchangeably with the term “inert gas”. The non-reactive gas may be mixed with a process gas to be used as a diluted inert gas or may be used as a purge gas for discharging a process gas from the inside of the substrate processing chamber 50.

In detail, an inert gas supply pipe 20, which is a part of the inert gas supply line 12, is installed on the roughly central portion of the shower head 5 facing the central portion of the substrate 1. The process gas supply pipe 15a, which is a part of the process gas supply line 6a, and the non-reactive gas supply pipe 15b, which is a part of the non-reactive gas supply line 6b, are connected to a peripheral portion of the shower head 5 facing the central portion of the substrate 1 other than the central portion thereof. That is, the process gas supply pipe 15a and the non-reactive gas supply pipe 15b are connected to portions of the shower head 5 which are away from the central portion of the shower head 5 connected to the inert gas supply pipe 20. An MFC 21 and the MFCs 16a and 16b are respectively installed on the inert gas supply pipe 20, the process gas supply pipe 15a and the non-reactive gas supply pipe 15b. The MFCs 21, 16a and 16b may independently control a flow rate of an inert gas including a non-reactive gas supplied into the substrate processing chamber 50 and a flow rate of a process gas. An inert gas supply source 22, the process gas supply source 17a and the non-reactive gas supply source 17b are respectively connected to the inert gas supply pipe 20, the process gas supply pipe 15a and the non-reactive gas supply pipe 15b. The gas supply lines 6a and 6b may further respectively include the process gas supply source 17a and the non-reactive gas supply source 17b. The inert gas supply line 12 may further include the inert gas supply source 22.

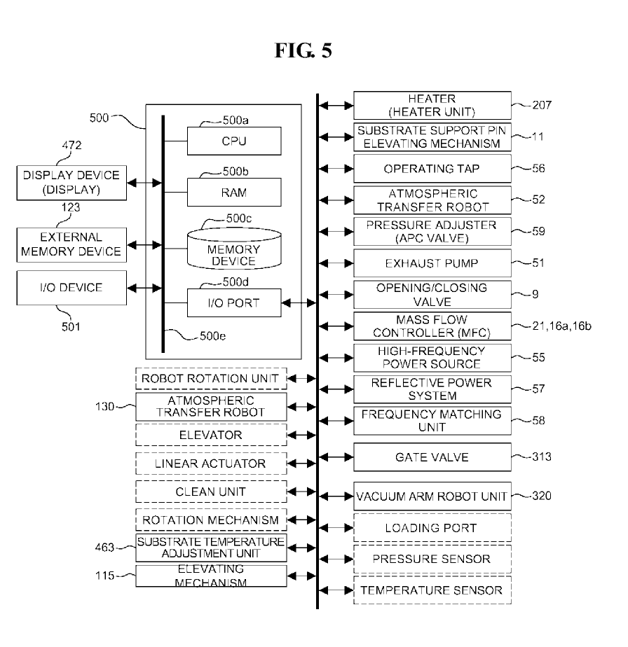

A structure of a controller 500 which is a control means for controlling various elements such as the elevating mechanism 115, the rotating mechanism, the resistive heater and the MFCs 21, 16a and 16b illustrated in FIGS. 1 through 3 are exemplified in FIG. 5.

### (Substrate Processing System)

Substrate processing performed by the substrate processing apparatus described above to remove a thin film from a substrate includes: loading the substrate 1 into the substrate processing chamber 50 (a loading step); processing the substrate 1 by supplying a process gas to the substrate 1 loaded into the substrate processing chamber 50 via the shower head 5 (a processing step); and unloading the processed substrate 1 from the substrate processing chamber 50 (an unloading step). Operations of a transfer system for performing the substrate processing, such as transferring the substrate 1, moving the susceptor 2 up/down, and moving the support pins 4 up/down, will be described by referring to those three steps (the loading step, the processing step and the unloading step).

In the loading step, the susceptor 2 is at the transfer position A and is in a state of heating the substrate 1. The opening/closing valve 9 of the processing container 30 is open. The substrate 1 is loaded from the substrate transfer chamber 40 into the substrate processing chamber 50 by a transfer mechanism (not shown) via the transfer port 8 and is then supported by the support pins 4 (see FIG. 2). The opening/closing valve 9 is closed after the substrate 1 is loaded into the substrate processing chamber 50. An inner atmosphere of the substrate processing chamber 50 is exhausted by a vacuum pump (not shown) via the annular exhaust channel 14a and the exhaust port 7.

In the processing step, first, the susceptor 2 is moved up by the elevating mechanism 115 from the transfer position A (see FIG. 2) to the substrate processing position B (see FIG. 1) having substantially the same height as the height of the annular member 14. Before arriving at the substrate processing position B, the substrate 1 is transferred from the support pins 4 by the susceptor 2. The substrate 1 is directly heated by the heater 207 of the susceptor 2. The substrate 1 transferred onto the susceptor 2 faces the shower head 5 at the substrate processing position B (see FIG. 1). The susceptor 2 is rotated by the rotating mechanism to rotate the substrate 1 if necessary.

A process gas is supplied to a surface of the substrate 1 within the substrate processing chamber 50 via the gas supply lines 6a and 6b and the shower head 5 as indicated by arrows in FIG. 1, and is exhausted via the annular exhaust channel 14a and the exhaust port 7. A film formed on the substrate 1 is removed by supplying the process gas to the surface of the substrate 1. An inert gas may be supplied into the substrate processing chamber 50 via the inert gas supply line 12 connected to the central portion of the shower head 5 facing the central portion of the substrate 1. In this case, a flow of the process gas supplied into the shower head 5 via a portion of the shower head 5 other than the central portion thereof may be controlled by the inert gas supplied into the substrate processing chamber 50 via the central portion of the shower head 5. The inert gas supplied into the substrate processing chamber 50 via the central portion of the shower head 5 may be efficiently discharged with the process gas by adjusting a flow rate of the exhaust gas flowing into the annular exhaust channel 14a through the adjusting unit 14b. After the film is removed, the process gas is discharged by the inert gas under a condition that congestion does not occur in the flow of the inert gas supplied to the central portion of the substrate 1 or that residues of the process gas are not generated on the surface of the substrate 1. The condition includes that the inert gas supplied to the substrate 1 via the inert gas supply pipe 20 flow radially and uniformly from a central portion of the surface of the substrate 1 to a circumferential portion thereof. A flow rate of an exhaust gas introduced to the annular exhaust channel 14a is adjusted by the adjusting unit 14b. The amount of a gas exhausted from the exhaust port 7 may be suppressed by adjusting the flow rate of the exhaust gas by the adjusting unit 14b. Thus, the inert gas introduced into the substrate processing chamber 50 via the central portion of the shower head 5 is adjusted to flow radially and uniformly from the central portion of the substrate 1 to the circumferential portion thereof without being concentrated and exhausted from the exhaust port 7. The exhaust gas stays in the annular exhaust channel 14a before it is exhausted via the exhaust port 7. Since the exhaust gas stays in the annular exhaust channel 14a, the amount of the exhausted gas is adjusted. In particular, according to the present embodiment, the flow of the inert gas on the substrate 1 may be easily adjusted by adjusting a supply rate thereof according to the flow rate of the inert gas and adjusting the amount of an exhausted gas using an element such as the annular member 14. As described above, the amount of the exhausted gas may be adjusted even on a surface of the substrate 1 on which the amount of the exhausted gas is difficult to adjust using the APC valve 59 and a vacuum pump (not shown) by appropriately controlling the flow rate of the inert gas supplied and appropriately configuring the gas exhaust system including the annular member 14. The MFC 21 installed at the inert gas supply pipe 12 adjusts the flow rate of the inert gas supplied via the inert gas supply pipe 20. As illustrated in FIG. 3, the substrate 1 may be moved up by the support pins 4 and then a process gas may be discharged (purged) by the inert gas.

After the substrate processing is completed, the susceptor 2 is moved down to the transfer position A in the unloading step (see FIG. 2). When the susceptor 2 is moved down, the support pins 4 move the substrate 1 up again to form a gap between the susceptor 2 and the substrate 1. The substrate 1 is unloaded to the substrate transfer chamber 40 by the transfer mechanism via the transfer port 8.

### (Gas Supply System)

The gas supply pipes 15a and 15b are installed in the lid 32 which is the upper part of the processing container 30. The shower head 5 configured to supply a halogen element-containing gas serving as a process gas to the substrate 1, is connected to the gas supply pipe 15a. The shower head 5 configured to supply a purge/diluted inert gas (here, N₂ gas) to the substrate processing chamber 50, is connected to the gas supply pipe 15b. A remover supply unit (not shown) which supplies, for example, a remover, which is a gas other than the process gas and the inert gas, to the substrate 1 and a supply unit (not shown) which supplies a cleaning gas such as chlorine fluoride gas (e.g., ClF₃) may be installed if necessary. The remover includes, for example, hydrogen fluoride gas for removing a modified layer (a natural oxide film). In the present embodiment, the remover may be a gas, but is not limited thereto. For example, the substrate 1 may be etched by supplying a remover which is a liquid thereto. Alternatively, the modified layer may be removed by sputtering a plasmified rare gas such as argon gas. The MFCs 16a and 16b which are flow rate controllers may be respectively installed at gas supply systems (the gas supply lines 6a and 6b) to control a gas supply rate. Gases to be used may be mixed together beforehand and supplied to the substrate processing chamber 50. A shower plate (not shown) may be used if necessary. Pressures of the processing container 30 and the substrate processing chamber 50 may be controlled to desired values by adjusting the amounts of a supplied gas and an exhausted gas using the MFCs 16a and 16b, which are flow rate controllers, and the APC valve 59.

### (Substrate Transfer System)

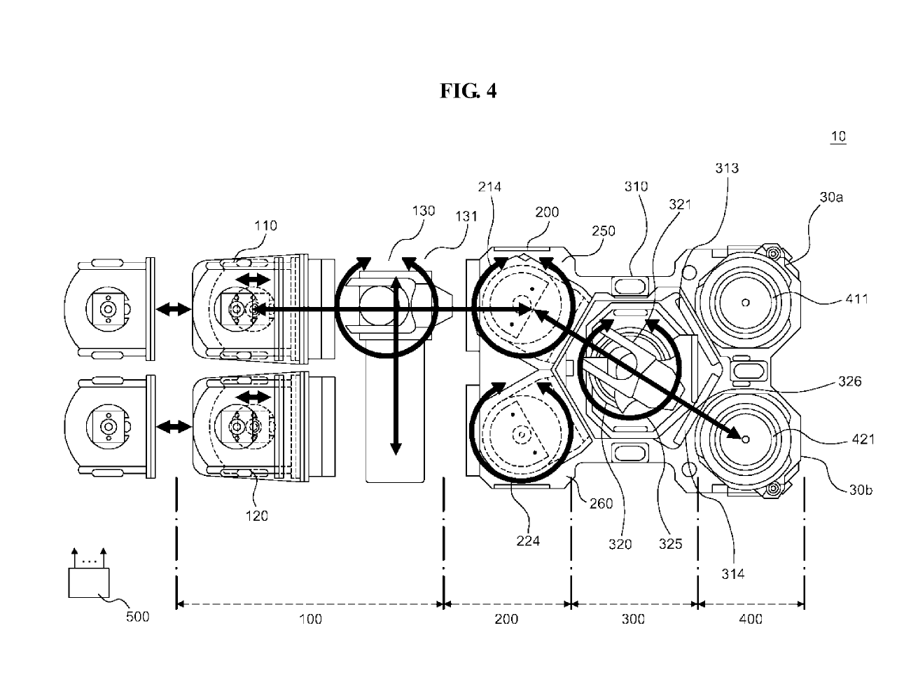

Next, a transfer system which transfers a substrate according to the present embodiment will be described with reference to FIG. 4. The transfer system which transfers a substrate includes an Equipment Front End Module (EFEM) 100, a load-lock chamber unit 200 and a transfer module 300.

The EFEM 100 includes Front Opening Unified Pods (FOUPs) 110 and 120 and an atmospheric transfer robot 130 which transfers the substrate 1 which is a wafer from each of the FOUPs 110 and 120 to the load-lock chamber unit 200. Twenty five substrates 1 are placed on the FOUPs 110 and 120, and an arm unit of the atmospheric transfer robot 130 takes five substrates 1 out of each of the FOUPs 110 and 120. Inner atmospheres of the EFEM 100 and the FOUPs 110 and 120 may be set to be an inert-gas atmosphere if necessary to suppress the substrates 1 from being naturally oxidized.

The load-lock chamber unit 200 includes load-lock chambers 250 and 260 and a buffer unit 224 which is configured to accommodate the substrates 1 transferred from the FOUPs 110 and 120 into the load-lock chambers 250 and 260. An inner atmosphere of the load-lock chamber unit 200 may be a vacuum atmosphere, an inert-gas atmosphere or a depressurized atmosphere with an inert gas being supplied thereto.

The substrate transfer chamber 40 includes a transfer module 310 serving as a transfer chamber, and the load-lock chambers 250 and 260 are connected to the transfer module 310 via a gate valve 313. A vacuum arm robot unit 320 serving as a second transfer unit is installed in the transfer module 310. An inner atmosphere of the substrate transfer chamber 40 may be a vacuum atmosphere, an inert-gas atmosphere or a depressurized atmosphere with an inert gas being supplied thereto. The inner atmospheres of the load-lock chamber unit 200 and the substrate transfer chamber 40 are preferably a depressurized atmosphere with an inert gas being supplied thereto so as to improve transferring throughput of the substrates 1 and suppress undesired oxygen from being adsorbed onto the substrates 1.

A processing chamber unit 400 includes processing chambers 30a and 30b. The processing chambers 30a and 30b are connected to the transfer module 310 via gate valves 313 and 314. In the present embodiment, the processing chamber 30a has the same construction as the processing chamber 30b.

### (Controller)

The controller 500 controls the above various elements to perform substrate processing, which will be described below.

### (Control Unit)

As illustrated in FIG. 5, the controller 500 which is a control unit (a control means) is embodied by a computer which includes a central processing unit (CPU) 500a, a random access memory (RAM) 500b, a memory device 500c and an input/output (I/O) port 500d. The RAM 500b, the memory device 500c and the I/O port 500d may exchange data with the CPU 500a via an internal bus 500e. An I/O device 501 such as a touch panel may be connected to the controller 200.

The memory device 500c is embodied by, for example, a flash memory or a hard disk drive (HDD). A processing recipe recording a control program for controlling an operation of a substrate processing apparatus or the order or condition of the substrate processing, which will be described below, is stored in the memory device 500c to be readable. The processing recipe is a combination of steps of the substrate processing, which will be described below, to obtain a desired result when the steps are performed by the controller 500, and acts as a program. Hereinafter, the processing recipe, the control program and the like will simply be referred to as a program. In the present disclosure, the term ‘program’ may be understood as including only the processing recipe, only the control program, or both of the processing recipe and the control program. The RAM 500b functions as a memory area (a work area) in which a program or data read by the CPU 500a is temporarily stored.

The I/O port 500d is connected to elements such as the substrate support pin elevating mechanism 11, the heater 207, the APC valve 59, the MFCs 21, the gas supply lines 16a and 16b, the opening/closing valve 9, an exhaust pump 51, an atmospheric transfer robot 52, the gate valve 313 and the vacuum arm robot unit 320. When the substrate processing apparatus further includes an excitation unit, the I/O port 500d may be also connected to a high-frequency power source 55, an operating tap 56, a reflective power system 57 and a frequency matching unit 58.

The CPU 500a reads the control program from the memory device 500c and runs the control program, and reads the processing recipe from the memory device 500c according to a manipulation command received via the I/O device 501. The CPU 500a is configured to, control moving of the support pins 4 up/down by the substrate support pin elevating mechanism 11, control heating/cooling of the substrates 1 by the heater 207, control pressure adjustment performed by the APC valve 59 and control adjusting of a flow rate of a process gas by the MFCs 21, the gas supply lines 16a and 16b and the opening/closing valve 9, based on the read process recipe. The substrate processing apparatus may further include, for example, elements such as a robot rotating unit or the atmospheric transfer robot 130 indicated by a broken line in FIG. 5. The CPU 500a may control, for example, the elements such as the robot rotating unit or the atmospheric transfer robot 130.

The controller 500 may be embodied by installing the above program stored in an external memory device 123 [e.g., a magnetic tape, a magnetic disk such as a flexible disk or a hard disk, an optical disc such as a compact disc (CD) or a digital versatile disc (DVD), a magneto-optical (MO) disc or a semiconductor memory such as a Universal Serial Bus (USB) memory or a memory card] in a computer. The memory device 500c or the external memory device 123 is a non-transitory computer-readable recording medium. Hereinafter, the memory device 500c and the external memory device 123 may also simply be referred to as a recording medium. In the present disclosure, the term ‘recording medium’ may be understood as including only the memory device 500c, only the external memory device 123 or both of the memory device 500c and the external memory device 123. When a program is supplied to a computer, a communication means such as the Internet or an exclusive line may be used without using the external memory device 123.

### (2) Substrate Processing

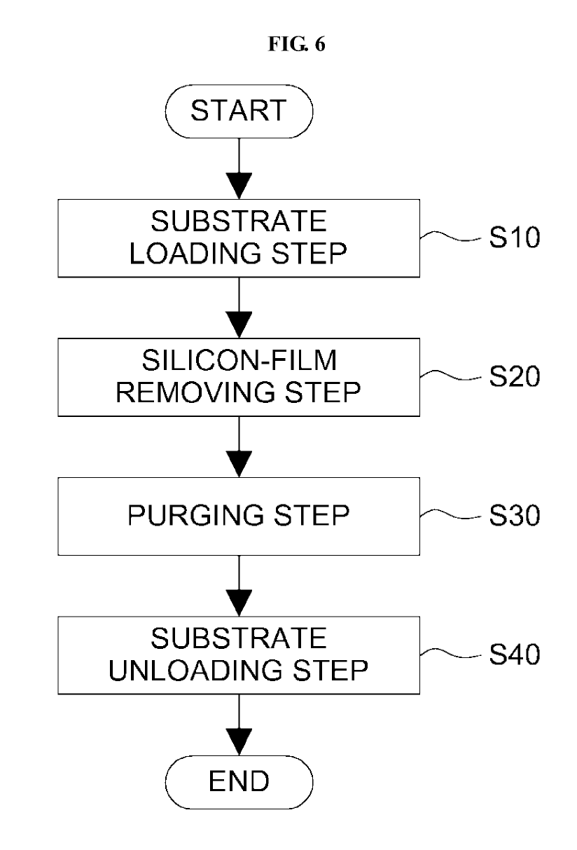

Next, substrate processing according to a first embodiment to a third embodiment will be described with reference to FIGS. 1 through 3 and 6. Steps of the first to third embodiments are performed by the substrate processing apparatus described above. Furthermore, in the present disclosure, operations of various elements of the substrate processing apparatus are controlled by the controller 500.

### First Embodiment

A substrate processing apparatus for performing a first embodiment includes: the substrate processing chamber 50 where the substrate 1 including a silicon film on a portion of surface thereof is processed; the elevating mechanism 115 configured to move the susceptor 2 on which the substrate 1 is placed up and down; the first gas supply system 6a configured to supply a halogen element-containing process gas to the substrate 1; the second gas supply system 6b configured to supply a purge gas (an inert gas) to the substrate 1 for discharging the process gas from the substrate processing chamber 50; the buffer exhaust pipe 14 installed near a sidewall of the substrate processing chamber 50 and configured to exhaust the process gas and the purge gas; and the controller 500 configured to control the first gas supply system 6a and the second gas supply system 6b to supply an exhaust gas to a central portion of the substrate 1 from thereabove and control the exhaust gas to flow radially on a surface of the substrate 1 from the central portion of the substrate 1 to a circumferential portion of the substrate 1 and to be discharged to the outside of the substrate processing chamber 50 via the buffer exhaust pipe 14, in a state in which a height of the susceptor 2 and a height of the buffer exhaust pipe 14 are adjusted to be the same. Substrate processing according to the first embodiment includes a substrate loading step (S10), a silicon-film removing step (S20), a purging step (S30) and a substrate unloading step (S40), which will be described below.

### [Substrate Loading Step (S10)]

First, as illustrated in FIG. 2, the substrate 1 including a silicon film on at least a portion of a surface thereof is transferred from the substrate transfer chamber 40 to the substrate processing chamber 50 by a substrate transfer robot via the transfer port 8.

### [Silicon-Film Removing Step (S20)]

Next, the support pins 4 are moved down to place the substrate 1 on the susceptor 2. The substrate support pin elevating mechanism 11 moves the support pins 4 up or down. The substrate 1 is heated in advance to a predetermined temperature by the heater 207 included in the susceptor 2. The substrate 1 is heated to room temperature (e.g., 25° C.) or a predetermined substrate temperature. A cooling mechanism for cooling reaction heat of the substrate 1 excessively heated may be used if necessary. In the silicon-film removing step (S20), the predetermined substrate temperature is in a range of temperatures at which a process gas may be sufficiently vaporized, and is a temperature at which the features of a film formed on the substrate 1, e.g., a silicon film, are not altered. The predetermined substrate temperature is, for example, between 30° C. and 50° C. For example, the predetermined temperature is 50° C. Then, the controller 500 controls various elements to move the susceptor 2 and the support pins 4 or only the susceptor 2 up and move the substrate 1 to the substrate processing position B by the elevating mechanism 115 to place the substrate 1 on the susceptor 2. Since the substrate 1 placed on the susceptor 2 is disposed at a position very near the gas supply unit, an inert gas supplied to the center of the substrate 1 radially flows from a central portion of the substrate 1 to a circumferential portion thereof. The susceptor 2 is adjusted such that the susceptor 2 [or the substrate processing position B] and the buffer exhaust pipe 14 [particularly, the adjusting unit 14b of the buffer exhaust pipe 14] have substantially the same height. Thus, the circumferential portion of the substrate 1 and the buffer exhaust pipe 14 approach each other and thus an exhaust gas including an inert gas smoothly flows to the annular exhaust channel 14a from the circumferential portion of the substrate 1 via the adjusting unit 14b of the buffer exhaust pipe 14. The susceptor 2 [or the substrate processing position B] may be set to be slightly higher than the buffer exhaust pipe 14.

Next, a silicon film formed on the substrate 1 is etched by supplying a certain process gas to the substrate 1 via the first gas supply system 6a and the shower head 5. The silicon film is etched by supplying an etching gas, which is the certain process gas, to the substrate 1. The etching gas may include a halogen-containing gas, e.g., a gas including at least one halogen element among fluorine (F), chlorine (Cl), brome (Br) and iodine (I). The etching gas may preferably include a gas including two types of halogen elements. For example, the etching gas may include any one of iodine pentafluoride (IF₅), iodine pentafluoride (IF₇), bromine trifluoride (BrF₃), bromine pentafluoride (BrF₅), xenon difluoride (XeF₂) and chlorine trifluoride (ClF₃). The etching gas preferably includes IF₇. IF₇ may selectively remove a silicon film. The selective removal of the silicon film should be understood as, for example, increasing an etching rate of the silicon film to be higher than that of another film (e.g., a SiO film, a SiN film, a metal film, or the like).

An inner pressure of the substrate processing chamber 50 is maintained to be the same as a predetermined pressure by adjusting the amount of an exhausted gas using the APC valve 59 while supplying the etching gas. The inner pressure of the substrate processing chamber 50 is maintained to be the same as, for example, a pressure between 0.1 and 100 Pa. A flow rate of the etching gas is about 0.1 to 10 slm. The flow rate of the etching gas is, for example, 3 slm. The etching gas may be supplied after an atmosphere of the substrate processing chamber 50 is exhausted, if necessary. Since the silicon film is etched by supplying the etching gas, the inner pressure of the substrate processing chamber 50 or the flow rate of the etching gas is preferably maintained to be the same as a predetermined value.

### [Purging Step (S30)]

The etching gas used in the etching of the silicon film (the silicon-film removing step) is discharged via the exhaust port 7 communicating with the annular exhaust channel 14a of the buffer exhaust pipe 14 installed at a side surface of the substrate processing chamber 50. Then, in the purging step (S30), an inert gas [e.g., nitrogen (N₂) gas] is supplied to the central portion of the substrate 1 via the inert gas supply pipe 20. The supplied inert gas flows radially and uniformly from the central portion of the substrate 1 to the circumferential portion of the substrate 1, smoothly flows to the annular exhaust channel 14a via the adjusting unit 14b of the buffer exhaust pipe 14, and is then discharged via the exhaust port 7. The efficiency of removing by-products generated when the silicon film is etched may be improved by supplying the inert gas to the central portion of the substrate 1 and adjusting the flow of the supplied inert gas on the substrate 1.

An inert gas may be supplied to the substrate 1 heated to a temperature higher than a sublimation temperature of at least one of a by-product and a residue generated during the etching of the silicon film in the purging step (S30). Thus, the generated by-product or residue may be efficiently discharged via the exhaust port 7 as the inert gas supplied to the central portion of the substrate 1 sublimates. Thus, the by-product generated during the etching of the silicon film may be more efficiently removed. Furthermore, the substrate 1 [a wafer] is preferably heated to a temperature which is higher than a sublimation temperature of at least one of the by-product and the residue generated during the etching of the silicon film and which is less than a heat-resistance temperature of a circuit formed on the substrate 1 or a heat-resistance temperature of an O-ring installed around the substrate processing chamber 50. The inert gas may be heated by a heating unit 23 and then supplied.

After the silicon-film removing step (S20) is completed, the supply of the process gas may be stopped, atmospheres of the processing container 30 and the substrate processing chamber 50 may be exhausted, the support pins 4 are moved up, the substrate 1 is separated from the susceptor 2 before the purging step (S30) is performed, and then the inert gas may be supplied to the substrate 1 via the inert gas supply pipe 20 and a roughly central portion of the shower head 5. Since the inert gas is supplied in the above state, the distance between the substrate 1 and an inert gas supply hole is decreased, and thus a by-product or a residue generated on the substrate 1 may be efficiently discharged.

### [Substrate Unloading Step (S40)]

When preparation for unloading the substrate 1 from substrate processing chamber 50 is completed by cooling the substrate 1 to a temperature at which the substrate 1 is transferrable, the substrate 1 is unloaded in an order opposite to that of the substrate loading step (S10) described above

### Effects of First Embodiment

The first embodiment provides at least one among the following effects (a) to (e).

(a) A silicon film may be efficiently removed by supplying a halogen element-containing process gas to an entire surface of a substrate and supplying an inert gas via a central portion of the substrate.

(b) The amount of a gas exhausted from an exhaust system may be suppressed by installing an adjusting unit on an annular member installed to surround an outer side of the substrate. Thus, an exhaust gas including a process gas may be suppressed from flowing on the substrate only in a direction of an exhaust port. Accordingly, the exhaust gas flows radially and uniformly on the substrate.

(c) The inert gas is supplied to the central portion of the substrate so that it flows radially from the central portion of the substrate to a circumferential portion thereof, thereby increasing the efficiency of discharging a by-product and a residue of the process gas.

(d) The efficiency of discharging a by-product and a residue of the process gas may be increased by heating the substrate to a temperature higher than a sublimation temperature of the by-product or residue of the process gas.

(e) The efficiency of discharging a by-product and a residue of the process gas may be increased by supporting the substrate by substrate support pins to shorten the distance between the substrate and an inert gas supply hole and then by supplying the inert gas.

### Second Embodiment

A substrate processing apparatus for performing a second embodiment includes: the substrate processing chamber 50 where the substrate 1 including a silicon film on a portion of surface thereof is processed; the first gas supply system 6a configured to supply a halogen element-containing process gas to the substrate 1; the second gas supply system 6b configured to supply a heated inert gas to the substrate 1; and the controller 500 configured to control the first gas supply system 6a and the second gas supply system 6b to supply the process gas and then supply the heated inert gas. Substrate processing according to the second embodiment includes a substrate loading step (S10), a silicon-film removing step (S20), a purging step (S30) and a substrate unloading step (S40), which will be described below. The second embodiment is different from the first embodiment only in that a heated inert gas is supplied into the substrate processing chamber 50 in the purging step (S30). Thus, the other steps of the second embodiment will be briefly described below. The second embodiment has the same effects as the first embodiment.

### [Substrate Loading Step (S10)]

Similar to the first embodiment, the substrate 1 including a silicon film on at least a portion of a surface thereof is transferred from the substrate transfer chamber 40 to the substrate processing chamber 50 by a substrate transfer robot via the transfer port 8.

### [Silicon-Film Removing Step (S20)]

Similar to the first embodiment, the substrate 1 is placed on the susceptor 2. The substrate 1 is heated in advance to a predetermined temperature by the heater 207 included in the susceptor 2. For example, the substrate 1 is heated to room temperature or a predetermined substrate temperature. Then, the susceptor 2 and the substrate support pin elevating mechanism 11 or only the susceptor 2 are moved up and the substrate 1 is placed on the susceptor 2 moved to the substrate processing position B.

Next, similar to the first embodiment, a silicon film on the substrate 1 is etched. A halogen-containing gas is used as an etching gas, similar to the first embodiment.

An inner pressure of the substrate processing chamber 50 and a flow rate of the etching gas are the same as those in the first embodiment. After the silicon film is etched, purging is preferably performed as a subsequent step.

When a modified layer having a thickness of about several atomic layers is formed on the silicon film, a removing gas which is a remover described above is preferably supplied to the substrate 1 before a process gas is supplied. The modified layer is, for example, an oxide film formed on the silicon film. Although the oxide film has a thickness of about several atomic layers, the oxide film cannot be removed by the process gas described above, and thus removing the silicon film becomes difficult. The modified layer may be removed while the silicon film or another film is retained by supplying the removing gas, and thus the silicon film may be finely removed by the process gas.

### [Purging Step (S30)]

The etching gas used to etch the silicon film is discharged via the exhaust port 7 communicating with the annular member 14 installed at a side surface of the substrate processing chamber 50. Then, an inert gas such as nitrogen gas is supplied to the substrate 1 via the inert gas supply pipe 20 and a roughly central portion of the shower head 5. The inert gas such as nitrogen gas is heated by the heating unit 23 and then supplied. The inert gas may be heated to a temperature higher than that of the above etching gas. A by-product generated when the silicon film is etched may be more efficiently removed by heating the inert gas to the temperature higher than that of the etching gas. Preferably, the inert gas is heated to a temperature higher than a sublimation temperature of at least one of by-products and the residue generated during the etching of the silicon film and supplied to the substrate 1 in the substrate processing chamber 50. Thus, the by-product generated during the etching of the silicon film may be more efficiently removed. The inert gas is preferably heated to a temperature which is higher than a sublimation temperature of at least one of the by-product and the residue generated during the etching of the silicon film and which is less than a heat-resistance temperature of a circuit formed on the substrate 1 or a heat-resistance temperature of an O-ring installed around the substrate processing chamber 50. A temperature of the substrate 1 may be controlled by the heater 207 as in the first embodiment.

Similar to the first embodiment, when the silicon-film removing step (S20) ends, the supply of the process gas may be stopped, and the inert gas may be supplied by moving the support pins 4 up and separating the substrate 1 from the susceptor 2 before the purging step (S30) is performed.

### [Substrate Unloading Step (S40)]

Similar to the first embodiment, when preparation for unloading the substrate 1 from substrate processing chamber 50 is completed by cooling the substrate 1 to a temperature at which the substrate 1 is transferrable, the substrate 1 is unloaded in an order opposite to that of the substrate loading step (S10) described above.

### Effect of Second Embodiment

In addition to the advantageous effects of the first embodiment, the second embodiment provides at least one among the following effects (f) to (j).

(f) At least one of a by-product and a residue of the process gas may be removed by supplying a heated inert gas.

(g) A by-product and a residue of the process gas may be more efficiently removed by heating the inert gas to a temperature higher than that of the process gas.

(h) The inert gas may be supplied to the substrate while suppressing a decrease in the temperature of the inert gas by supplying the inert gas via a central portion of the substrate instead of a shower head.

(i) The efficiency of heating the substrate may be improved by supplying the heated inert gas with the substrate supported by substrate support pins to shorten the distance between the substrate and a hole via which the heated inert gas is supplied. When the heated inert gas is used, at least one of a by-product and a residue of the process gas may be more efficiently removed.

(j) When the inert gas heated to a temperature higher than a sublimation temperature of a by-product and a residue of the process gas is supplied, at least one of the by-product and the residue of the process gas may be more efficiently removed.

### Third Embodiment

A substrate processing apparatus for performing a third embodiment includes: the substrate processing chamber 50 where the substrate 1 including a silicon film on at least a portion of a surface thereof is processed; the first gas supply system 6a configured to supply a halogen element-containing process gas to the substrate 1; the second gas supply system 6b configured to supply a heated inert gas to the substrate 1; and the controller 500 configured to control the first gas supply system 6a and the second gas supply system 6b to simultaneously supply the process gas and the heated inert gas.

A configuration of the third embodiment is the same as that of the second embodiment except that the process gas and the heated inert gas are simultaneously supplied. Thus, only the differences between the third embodiment and the second embodiment will be described below. The description is assumes that the process gas is IF₇ gas.

When the process gas and the heated inert gas are simultaneously supplied, they are mixed in the substrate processing chamber 50. Thus, the process gas is heated to, for example, about 50° C.

The silicon film may be selectively removed by supplying a mixed gas of the process gas and the inert gas to the substrate 1. The substrate 1 may not be heated by the heater 207. However, since a temperature of the process gas on the substrate 1 may decrease to a temperature of liquefaction, the substrate 1 may be heated by the heater 207 if necessary. After a predetermined time elapses, the supply of the process gas is stopped and the purging step (S30), which is a subsequent step, is performed.

In the purging step (S30), the substrate 1 is preferably heated by the heater 207 to a temperature higher than a sublimation temperature of a by-product or a residue so as to remove the by-product or the residue which is difficult to discharge with only the inert gas. In the purging step (S30), the inert gas need not be heated.

According to the third embodiment, when the silicon film is removed, the substrate 1 need not be heated by the heater 207, and thus power consumption may be suppressed.

### Other Embodiments

Embodiments have been described above in detail. The technique is not limited thereto and may be embodied in many different forms without departing from the scope of the technique.

The technique is applicable to, for example, a substrate processing apparatus such as a film forming apparatus which forms a film on a substrate or a thermal treatment apparatus which thermally processes a substrate. For example, when a boiling point of a gas which contributes to forming a film is high and the gas remains on a surface of a substrate or the like, the remaining gas may be more efficiently removed by supplying an inert gas. Furthermore, the scope of the technique is not limited in the number of substrates to be simultaneously processed, a direction in which the substrates are retained, the type of a diluted gas or purge gas, a cleaning method or the shape of a substrate process chamber, a heating mechanism or a cooling mechanism.

The technique described herein is not limited to a semiconductor manufacturing apparatus for processing a semiconductor wafer, such as the substrate processing apparatus according to the above embodiments. The technique is also applicable to, for example, a liquid crystal display (LCD) manufacturing apparatus for processing a glass substrate, a substrate processing apparatus such as a solar cell manufacturing apparatus, or a micro-electro-mechanical systems (MEMS) manufacturing apparatus. The technique is also applicable to, for example, processing monocrystalline silicon, polycrystalline silicon or amorphous silicon for use in a transistor for driving an LCD or a solar cell.

According to the technique described, the quality of a manufactured semiconductor device may be improved.

The technique can be applied to processing monocrystalline silicon, polycrystalline silicon or amorphous silicon for use in a device such as a transistor for driving an LCD or a solar cell and a semiconductor device such as a memory.

What is claimed is:

1. A substrate processing apparatus comprising:
a processing chamber where a substrate including a silicon film on a portion of surface thereof is processed;
a substrate holding part whereon the substrate is placed;
an elevating mechanism configured to move the substrate holding part up and down;
a first gas supply system configured to supply a process gas containing a halogen element to the substrate;
a second gas supply system configured to supply an inert gas for exhausting the process gas out of the processing chamber to the substrate;
an exhaust unit disposed about a sidewall of the processing chamber and configured to exhaust the process gas and the inert gas; and
a controller configured to control the elevating mechanism, the first gas supply system and the second gas supply system to: supply the process gas with a state where a height of the substrate holding part and a height of the exhaust unit are adjusted; and supply the inert gas to a center portion of the substrate from thereabove such that the inert gas flows radially from the center portion to a circumferential portion of the substrate along a surface of the substrate and is exhausted out of the processing chamber through the exhaust unit.

2. The substrate processing apparatus of claim 1, wherein the first gas supply system is configured to supply the process gas to an entire surface of the substrate from thereabove, and the second gas supply system is configured to supply the inert gas to the center portion of the substrate from thereabove.

3. The substrate processing apparatus of claim 1, further comprising a heating unit configured to heat the substrate to a temperature higher than room temperature.

4. The substrate processing apparatus of claim 3, wherein the heating unit is configured to heat the substrate to a temperature higher than a sublimation temperature of by-products or residues.

5. The substrate processing apparatus of claim 1, further comprising a gas supply unit disposed above the substrate holding part and connected to the first gas supply system to supply the process gas through holes disposed on an entire surface thereof.

6. The substrate processing apparatus of claim 1, further comprising support pins configured to support the substrate in the processing chamber wherein the controller is further configured to control the first gas supply system to supply the process gas to the substrate while the substrate is placed on the substrate holding part and the second gas supply system to supply the inert gas to the substrate while the substrate is placed on the support pins.

7. The substrate processing apparatus of claim 1, wherein the exhaust unit comprises: an adjusting unit configured such that flow rates of the process gas and the inert gas exhausted from the processing chamber are adjusted thereby; and an annular exhaust channel where the process gas and the inert gas introduced through the adjusting unit flow.

8. The substrate processing apparatus of claim 1, wherein the process gas comprises at least one selected from a group consisting of fluorine, chlorine, bromine, iodine, iodine pentafluoride, iodine heptafluoride, bromine trifluoride, bromine pentafluoride xenon difluoride and chlorine trifluoride.

9. A substrate processing apparatus comprising:
a processing chamber where a substrate including a silicon film on a portion of surface thereof is processed;
a process gas supply system configured to supply to the substrate a process gas containing a halogen element;
an inert gas supply system configured to supply a heated inert gas to the substrate; and
a controller configured to control the process gas supply system and the inert gas supply system to supply the heated inert gas to the substrate after supplying the process gas.

10. The substrate processing apparatus of claim 9, further comprising a showerhead disposed above the substrate and connected to the process gas supply system, wherein the process gas supply system is further configured to supply the process gas through holes disposed on an entire surface of the showerhead and the inert gas supply system is further configured to supply the heated inert gas to a center portion of the substrate from thereabove.

11. The substrate processing apparatus of claim 9, wherein a temperature of the heated inert gas is higher than that of the process gas.

12. The substrate processing apparatus of claim 9, wherein a temperature of the heated inert gas is higher than at least one of sublimation temperatures of by-products and residues.

13. The substrate processing apparatus of claim 9, further comprising: a substrate holding part disposed in the processing chamber whereon the substrate is placed; and support pins configured to support the substrate in the processing chamber, wherein the controller is further configured to control the process gas supply system to supply the process gas to the substrate while the substrate is placed on the substrate holding part and the inert gas supply system to supply the heated inert gas to the substrate while the substrate is placed on the support pins.

14. A substrate processing apparatus comprising:
a processing chamber where a substrate including a silicon film on a portion of surface thereof is processed;
a process gas supply system configured to supply to the substrate a process gas containing a halogen element;
an inert gas supply system configured to supply a heated inert gas to the substrate; and
a controller configured to control the process gas supply system and the inert gas supply system to simultaneously supply the process gas and the heated inert gas to the substrate.
